(19) United States
(12) Patent Application Publication
(10) Pub. No.: US 2025/0093449 A1
(43) Pub. Date: Mar. 20, 2025

(54) METHOD FOR GENERATING A SERIES OF MAGNETIC RESONANCE IMAGES WITH CROSS-FRAME ITERATIVE RECONSTRUCTION

(71) Applicant: Bruker BioSpin GmbH & Co. KG, Ettlingen (DE)

(72) Inventor: Michael HERBST, Freiburg (DE)

(21) Appl. No.: 18/883,709

(22) Filed: Sep. 12, 2024

(30) Foreign Application Priority Data
Sep. 14, 2023 (DE) 10 2023 208 954.8

(51) Int. Cl. G01R 33/561

(52) U.S. Cl. CPC G01R 33/5611; G01R 33/5616

(57) ABSTRACT

The invention relates to a method for generating a series of magnetic resonance images from an MR bin series obtained by means of an MRI measurement, wherein the MR bin series comprises a plurality of bin frames (f1, f2, f3) with determined MR data, wherein at least one bin frame is undersampled, i.e., has missing MR data in addition to the determined MR data, wherein the bin frames differ by the value of x prespecified parameters (x=1 or greater) under which the MR data were determined, comprising: a) calculating an n-dimensional preliminary reconstruction kernel from preliminary reference data of a reference frame; b) determining preliminary reconstruction frames by reconstruction of the MR data missing in the MR bin series by means of the preliminary reconstruction kernel; c) calculating an n+x-dimensional reconstruction kernel by calculation from the MR data of the preliminary reconstruction frames, wherein MR data of different preliminary reconstruction frames are used for the calculation of the n+x-dimensional reconstruction kernel; d) determining further reconstruction frames by reconstructing the data missing in the bin frames by means of the n+x-dimensional reconstruction kernel; e) generating n-dimensional magnetic resonance images from the reconstruction frames determined in step (d).

### BACKGROUND OF THE INVENTION

### Field of the Invention

The invention relates to a method for generating a series of n-dimensional magnetic resonance images from an MR bin series obtained by means of an MRI measurement, wherein the MR bin series comprises a plurality of bin frames with determined MR data, wherein at least one bin frame is undersampled, i.e., has missing MR data in addition to the determined MR data, wherein the bin frames differ by the value of x prespecified parameters (x=1 or greater) under which the MR data were determined. A method of this kind is known from patent document US 2006/0050981 A1.

### Description of the Related Art

Magnetic resonance imaging (MRI) is a widely used technique for non-invasively obtaining images of the interior of an object under examination, in which nuclear spins oriented in the direction of a main magnetic field (z-direction) are stimulated by the radiation of electromagnetic RF pulses (RF:radio frequency). By time-varying superpositions of additional location-dependent magnetic fields for all three spatial directions, a spatial encoding is generated which can be described as the traversal of a trajectory in the k-space, the so-called k-space trajectory. MR signals are recorded during traversal of the k-space trajectory. A data set comprising N×M data voxels is obtained. An MR image is generated in image space by Fourier transformation.

In order to shorten the acquisition time for MRI scans, it is known to reduce the amount of image data to be acquired by incompletely sampling the k-space during one scan with a plurality of (real and/or virtual) detection coils (parallel imaging). This means that fewer than NxM encoding steps are performed, resulting in a reduced data set for each coil. To obtain a complete image from such a reduced data set, the missing data need to be reconstructed. For this purpose, reference data are used to determine a reconstruction kernel, from which data the undersampled measurement can be completely reconstructed.

A reconstruction kernel is used for reconstruction of MR data (intensity and phase values in the k-space) from undersampled data sets resulting from an MR measurement in which the k-space was not completely sampled. To calculate (calibrate) a reconstruction kernel, a mathematical relationship (linear combination) of reference points and target points within the reference data is determined (linear interpolation). The reconstruction kernel therefore comprises the specification of how the MR data are to be taken into account in the reconstruction. The reconstruction kernel describes the influence of recorded data voxels (determined MR data) on a data voxel to be reconstructed (missing MR data). The reconstruction kernel therefore comprises the weighting of the measured points when reconstructing a target point. The size of the reconstruction kernel indicates how many measurement points of the reference data are used for the calculation of the reconstruction kernel.

Patent document DE 10 2020 202 576 B4 and M. Herbst, Autocalibrating segmented diffusion-weighted acquisitions, Magn Reson Med. 2021;00:1-14 disclose a method in which the missing data of the MR segment data sets are reconstructed twice: First, preliminarily reconstructed MR segment data sets are calculated by means of a reconstruction kernel obtained from reference data. By creating phase images from the preliminarily reconstructed MR segment data sets and adding these phase images to the reference image, modified reference images are obtained that contain phase information. From this, the second reconstruction kernels are determined, which, in contrast to the first reconstruction kernel, contain phase information. In this way, the missing data of the MR segment data sets can be reconstructed without phase artifacts.

For dynamic magnetic resonance imaging, an object is imaged in motion by recording a series of images at a high frame rate and dividing the images into frames, wherein, within a frame, data are contained that are assigned to a specific point in time within the motion cycle (time frame), e.g., the diastole during a heartbeat. Methods in which different time frames are generated are known from US 2006/050981 A1, Patent document DE 10 2007 015 040 B3, T. Zhao, X. Hu, Iterative GRAPPA (iGRAPPA) for Improved Parallel Imaging Reconstruction, Magnetic Resonance in Medicine 59:903-907 (2008) (hereinafter “Zhao”), and F. Breuer et al., Dynamic Autocalibrated Parallel Imaging Using Temporal GRAPPA (TGRAPPA), Magnetic Resonance in Medicine 53:981-985 (2005) (hereinafter “Breuer”).

US 2006/050981 A1 and DE 10 2007 015 040 B3 disclose reconstruction methods in which different time frames are used to generate the reconstruction kernel. Data from neighboring frames is used (kt-GRAPPA). This method thus uses the influence of neighboring temporal information to improve the quality of the reconstruction. The disadvantage of these methods is that reference data are required for each frame, which data are usually recorded as part of each measurement in the series. This procedure extends the necessary measurement time.

Zhao discloses a reconstruction method in which, in order to keep the amount of required reference data low, a small reconstruction kernel is first calibrated. With this small reconstruction kernel, a reconstruction (with artifacts) is performed. From this reconstruction, a larger reconstruction kernel is then calibrated (i-GRAPPA), which can be used for a reconstruction with few artifacts. However, only data within the corresponding time frame is taken into account in this case.

Another possibility for generating a reconstruction kernel is to summarize (average) parts of the measurement series that have different encoding. Such a method is known from Breuer (t-GRAPPA). The reconstruction kernel generated in this way contains information/data from different time frames, but no information about how the data from different time frames relate to each other. This method does not require any reference data within the time frames. However, the time resolution for calibration is reduced due to averaging, and the requirements for the length of the measurement series, the phase consistency of the data, and the encoding are increased.

### SUMMARY OF THE INVENTION

The invention provides a method in which the information from neighboring frames is used for the calibration of the reconstruction kernel, and, at the same time, the measurement time is shortened.

The method according to the invention comprises the following method steps:
a) calculating an n-dimensional preliminary reconstruction kernel from preliminary reference data of a reference frame;
b) determining preliminary reconstruction frames by reconstruction of the MR data missing in the MR bin series by means of the preliminary reconstruction kernel;
c) calculating an n+x-dimensional reconstruction kernel from the MR data of the preliminary reconstruction frames, wherein MR data of different preliminary reconstruction frames are used for the calculation of the n+x-dimensional reconstruction kernel;
d) determining further reconstruction frames by reconstructing the data missing in the bin frames by means of the n+x-dimensional reconstruction kernel;
e) generating n-dimensional magnetic resonance images from the reconstruction frames determined in step (d).

A binning frame, or bin frame for short, contains only MR data for which the prespecified parameter has a predetermined value (e.g., a specific diffusion gradient) or lies in the same predetermined parameter interval (e.g., a specific time interval). For example, the mean value of the parameter interval can be used as a representative value of the parameter in a parameter interval.

An MR bin series is obtained by a plurality of scans that acquire k-space data (MR data) at defined k-points in a k-space. The MR bin series comprises a plurality of bin frames and can be represented as a k-t-sampling pattern of acquired data in the k-t-space.

During a scan, MR data (k-space data voxels) are acquired using a specific value of the prespecified parameter (e.g., using a specific diffusion gradient or at a specific point in time during a cycle). For example, the k-space data of each scan form a Cartesian grid in two dimensions of the k-space, ky and kx, where ky is the phase encoding direction, and kx is the frequency encoding direction or another phase encoding direction. For three dimensions, a phase encoding direction kz is added. The totality of scans for a prespecified parameter forms a bin frame.

A reconstruction frame comprises the MR data of the corresponding bin frame as well as the reconstructed data of the data missing in the corresponding bin frame.

According to the invention, a preliminary n-dimensional reconstruction kernel is first calculated, with the help of which preliminary reconstruction frames are determined. The data from the preliminary reconstruction frames then serve as reference data to determine the n+x-dimensional reconstruction kernel. The dimension of a reconstruction kernel is determined in particular by the dimensions in which reconstruction is to be performed, the number of coils used for the measurement (parallel imaging), and the number of parameters that are decisive for the division of the data into bin frames. The number of coils is not relevant for the inventive idea and will therefore not be taken into account further. Compared to the n-dimensional preliminary reconstruction kernel, the dimension of the n+x-dimensional reconstruction kernel is larger by the number x of parameters whose values are decisive for the differentiation of the bin frames.

The MR images are determined from the further reconstruction frames, e.g., (in the case of reconstruction in the k-space) by Fourier transformation.

The MR bin series, which serves as the basis for the method according to the invention, is obtained by means of an MRI measurement.

While, for example, in diffusion-weighted imaging, the value of the parameter (diffusion gradient) is changed discretely (and thus the MR data can already be assigned to the corresponding bin frames by applying the diffusion gradient), the MR data must be divided into discrete “bins” if the parameter changes continuously (e.g., point in time within a cycle in a cardiac measurement). The MR data are sorted according to parameter values and divided into different “bins” to form “bin frames.” The values of the prespecified parameters are therefore decisive for the division of the MR data into the different bin frames. In other words, bin frames differ by the value of the prespecified parameter.

Each bin frame (f1, f2, f3) can contain MR data from different detection coils (parallel imaging). Detection coils can be both real and virtual, wherein virtual coils are able to be generated either from the combination of a plurality of real coils or from individual real coils, taking into account the symmetry properties of the k-space as described in DE 10 2020 202 576 B4. Bin frames are usually undersampled, i.e., MR data are not measured for the entire k-space, so that MR data are missing in the bin frames. Preferably, a bin frame comprises MR data of all coils used, provided that the prespecified parameter for the MR data lies in the same parameter interval.

Preferably, an echo-planar imaging (EPI) measurement sequence is used for the MRI measurement. The MR data are preferably recorded by means of a single-shot measurement. This variant is particularly advantageous, because no implicit reference data can be measured during the EPI scan.

In a special variant of the method according to the invention, the at least one prespecified parameter is the direction and/or the amplitude of the diffusion gradients used in the MRI measurement.

The MR bin series is measured in this case by means of diffusion-weighted magnetic resonance imaging (DW MRI). In this variant, a bin frame (diffusion frame) contains MR data that were measured by applying a specific diffusion gradient.

In this variant, an MR bin series (in this case: diffusion series) comprises a plurality of diffusion frames.

In a further variant, the at least one prespecified parameter comprises the time coordinate within a cycle. A specific time coordinate within a cycle is a point in time at a specific time distance from the beginning of the cycle.

In this variant, the bin frames are called time frames. A periodically repeating event is recorded (e.g., a movement pattern, in particular heartbeat, breathing). In this variant, the time frame contains the MR data recorded at a specific cycle point in time/cycle time interval. In the case of a periodic event, the MR data within a time frame therefore do not have to be recorded directly one after the other, but, rather, at a specific cycle point in time/time interval (for example, in relation to the diastole of a heart chamber).

In this variant, an MR bin series (in this case: time series) comprises a plurality of time frames.

In a further variant, the at least one prespecified parameter comprises an echo time or inversion time used in the MRI measurement.

In this case, too, the bin frames are referred to as time frames. In this variant, the time frame contains the MR data recorded in a specific time interval (within the echo time). This variant is applied in particular when non-periodic events are to be recorded.

In another variant, the MR bin series can also be measured using flow-sensitive MR sequences. The encoding gradient, which is relevant for the flow direction depicted, then serves as a parameter.

The encoding of the MR data in the MR bin frames can be periodic, wherein preferably a GRAPPA (generalized autocalibrating partially parallel acquisitions) or CAIPIRINHA (controlled aliasing in parallel imaging results in higher acceleration) reconstruction method is applied. Alternatively, it is also possible that the encoding of the MR data in the MR bin frames is irregular in at least one dimension, wherein a SPIRIT reconstruction method is preferably applied.

Preferably, only bin frames the values of which for the prespecified parameter lie within a prespecified interval (neighboring bin frames) are used to reconstruct the missing data of a bin frame. This ensures that bin frames used for reconstruction contain information about the further reconstruction frame to be reconstructed.

“Neighboring bin frames” do not have to be recorded consecutively in time, but are similar only in their parameter value.

Neighboring diffusion frames are understood to mean diffusion frames the MR data of which have been recorded with similar diffusion gradients, i.e., with diffusion gradients that cause no or no significant changes in the information to be derived from the MR images. Directly neighboring diffusion frames are diffusion frames that contain MR data acquired with the next or previous used value of the diffusion gradient or echo time.

Neighboring time frames are time frames the MR data of which have been recorded at similar cycle times. Parameter values are considered similar if the changes in the MR image and/or in the k-space data resulting from the different parameter values are within a prespecified acceptance range (i.e., if the changes in the MR images resulting from the different parameter value do not significantly affect the information to be derived from the MR images and are therefore considered acceptable by the user).

Preferably, the MR bin series is ordered with respect to the parameter (if it is not already ordered), so that the MR data are included in the correct order during the calibration of the n+x-dimensional reconstruction kernel.

The value of the prespecified parameter is not similar for all bin frames of an MR bin series. The reconstruction kernel is nevertheless (typically) calculated from all bin frames of the MR bin series. However, only MR data from its own and neighboring bin frames are used for the reconstruction of the data voxels (missing data). The number of bin frames used (i.e., neighboring bin frames) in the reconstruction is defined by the size of the reconstruction kernel: the more the parameters of the bin frames differ, the smaller is the size of the reconstruction kernel selected in the “parameter dimension.” This means that only a few bin frames are taken into account during reconstruction. The size of the n+x-dimensional reconstruction kernel, or the number of “neighboring” bin frames, is preferably in the range of 2-10. The selection of the kernel size is described in detail in DE 10 2007 015 040 B3.

Preferably, the n-dimensional preliminary reconstruction kernel is a t-GRAPPA kernel, i.e., a kernel that is determined by summing/averaging the MR data of different time frames. In this case, no reference measurement is necessary, since the MR data for creating the preliminary reconstruction kernel are data from the MR bin series. This eliminates the need for a fully sampled reference measurement.

Alternatively, the preliminary reconstruction kernel can also be calculated from a fully sampled reference measurement.

Preferably, the MR bin series comprises bin frames with different encoding, in particular different phase encoding.

In a special variant of the method according to the invention, the encoding of the MR data of the bin series is periodic, and preferably a GRAPPA (generalized autocalibrating partial parallel acquisition) reconstruction method, in particular a CAIPIRINHA (controlled aliasing in parallel imaging results in higher acceleration) reconstruction method, is applied. This allows for rapid reconstruction.

Alternatively, the encoding of the MR data is irregular, and preferably a SPIRiT (iterative self-consistent parallel imaging reconstruction from arbitrary k-space) reconstruction method is applied. This method can also be used to reconstruct data that (in contrast to the MR data obtained in a scan) do not lie on a Cartesian grid in the k-space.

To further improve the quality of the reconstruction, steps c) and d) can be repeated, wherein the calculation of the n+x-dimensional reconstruction kernel in step c) is carried out from the MR data of the previously determined further reconstruction frames.

Preferably, the reconstruction in step (d) takes place in the k-space. The MR data are therefore frequency data.

Alternatively, parts of the reconstruction or the entire reconstruction could also be carried out in the image space.

Further advantages of the invention can be found in the description and the drawings. Likewise, according to the invention, the aforementioned features and those which are to be explained below can each be used individually or together in any desired combinations. The embodiments shown and described are not to be understood as an exhaustive list, but, rather, have an exemplary character for the description of the invention.

### BRIEF DESCRIPTION OF THE DRAWINGS

FIG. 1 schematically shows the method according to the invention.

FIG. 2 shows a reference frame during calibration of the preliminary reconstruction kernel, undersampled bin frames during reconstruction, and preliminary reconstruction frames during calibration of the n+x-dimensional reconstruction kernel, wherein the undersampled bin frames are encoded identically.

FIG. 3 shows a reference frame during calibration of the preliminary reconstruction kernel, undersampled bin frames during reconstruction, and preliminary reconstruction frames during calibration of the n+x-dimensional reconstruction kernel, wherein the bin frames are differently encoded.

### DETAILED DESCRIPTION

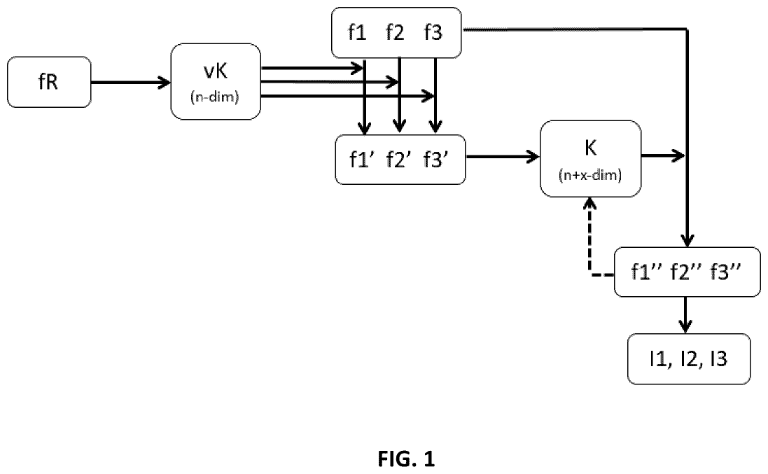

FIG. 1 schematically shows the method according to the invention, with which a series of MR images l1, l2, l3 is generated from a bin series with undersampled bin frames f1, f2, f3. For simplicity, only three bin frames f1, f2, f3 are shown in the figures.

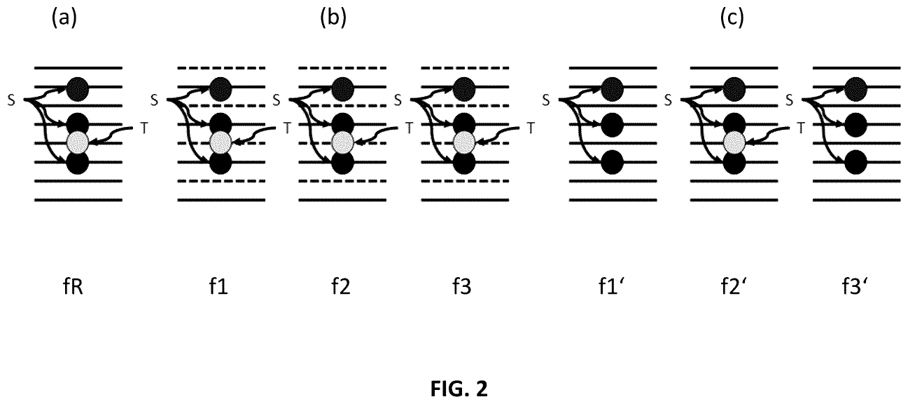

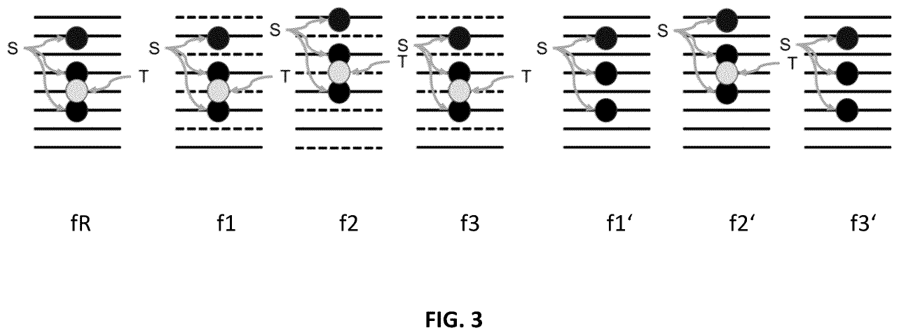

First, an n-dimensional preliminary reconstruction kernel vK is calculated from a reference frame fR as part of a calibration (see also FIG. 2 and FIG. 3).

Using the n-dimensional preliminary reconstruction kernel vK, a reconstruction of the individual undersampled bin frames f1, f2, f2 is performed. The result of this reconstruction is a preliminarily reconstructed reconstruction series with preliminary reconstruction frames f1′, f2′, f3′. According to the invention, the (in the k-space) undersampled bin series of MR measurements is individually reconstructed using parallel imaging (preliminary reconstruction).

The preliminary reconstruction frames f1′, f2′, f3′ are now used to calculate a higher-dimensional (n+x-dimensional) reconstruction kernel K, which contains cross-bin frame relationships between target points (points/data voxels that correspond to the data/data voxels missing in bin frames f1, f2, f3) and reference points (points/data voxels that correspond to the MR data/data voxels determined in bin frames f1, f2, f3). This is shown in more detail in FIGS. 2 and 3. The preliminary reconstruction series therefore represents a reference data set that allows the determination of a reconstruction rule taking into account neighboring measurements (bin frames) of the bin series. How much higher the dimension of the reconstruction kernel K is than that of the preliminary reconstruction kernel vK depends upon the number x of parameters used to distinguish the bin frames.

Using the n+x-dimensional reconstruction kernel K, a further reconstruction of the undersampled bin frames f1, f2, f2 is performed. The result of this reconstruction is another reconstructed series with further reconstruction frames f1″, f2″, f3″, from which MR images l1, l2, l3 can then be generated by means of Fourier transformation. To improve the result, an n+x-dimensional reconstruction kernel can be calculated again from the further reconstruction frames f1″, f2″, f3″, and the bin frames f1, f2, f3 can be reconstructed again with the recalculated reconstruction kernel (indicated by dashed lines in FIG. 1). This can be repeated as often as required before the MR images l1, l2, l3 are generated.

FIG. 2 and FIG. 3 show different bin frames in the k-space, wherein acquired MR data are shown as solid lines and missing data as dashed lines. In addition, reference points S and target points T are shown, which are used here by way of example for calculating the reconstruction kernels.

In the region (a) of FIG. 2 and FIG. 3, the calibration of the preliminary reconstruction kernel vK from the reference frame fR is shown schematically. The reference frame fR is fully sampled, but can be smaller than the bin frames. The preliminary reconstruction kernel vK calculated from the reference frame fR contains the mathematical relationship between target points T and reference points S of the reference frame fR.

In the region (b) of FIG. 2 and FIG. 3, the preliminary reconstruction by means of the preliminary reconstruction kernel vK is shown schematically. FIG. 2 and FIG. 3 show that each undersampled bin frame f1, f2, f3 is individually reconstructed using the mathematical relationship between target points T and reference points S of the preliminary reconstruction kernel vK, thereby obtaining the preliminary reconstruction frames f1′, f2′, f3′ shown in region (c) of FIG. 1. By means of the preliminary reconstruction kernel vK, all missing data (target points T) of all bin frames f1, f2, f3 have been determined.

The n+x-dimensional reconstruction kernel K is now calculated from the preliminary reconstruction frames f1′, f2′, f3′, which kernel comprises the cross-frame mathematical relationship between target points T (shown by way of example as a target point T of the preliminary reconstruction frame f2′) and reference points S from the various preliminary reconstruction frames f1′, f2′, f3′. This is shown schematically in the region (c) of FIG. 2 and FIG. 3. Linear combinations are determined that establish a relationship between reference points S of different bin frames f1′, f2′, f3′ and target points T. For each target point T, there is a linear combination that contains reference points from different frames.

In the variant shown in FIG. 2, all bin frames f1, f2, f3 are encoded identically (indicated by the same sequence of solid and dashed lines). In this variant, the reference frame fR is preferably generated by a fully sampled preliminary measurement (reference measurement).

Alternatively, the reference frame fR can also be generated by summing the MR data of different neighboring bin frames f1, f2, f2 of the undersampled bin series.

The prerequisite for this is that bin frames are encoded differently, as shown in FIG. 3. In FIG. 3, only the bin frames f1 and f3 are encoded identically, while the bin frame f2 has a different encoding. Specifically, in the example shown, the encodings are selected such that the missing data in bin frame f1 (dashed lines) are present in bin frame f2 (solid lines) and vice versa, so that a fully sampled reference frame can be obtained by summing the bin frames f1 and f2.

In the context of the invention described here, a reference frame is always fully sampled. Despite the same dimensionality, the size of the reference frame can be smaller than that of the magnetic resonance images or bin frames. For example, a reference frame can only correspond to the central area of a magnetic resonance image or bin frame.

### LIST OF REFERENCE SIGNS

f1, f2, f3 Bin frames
f1′, f2′, f3′ Preliminary reconstruction frames
f1″, f2″, f3″ Further reconstruction frames
fR Reference frame
K Reconstruction kernel
vK Preliminary reconstruction kernel
l1, l2, l3 MR images
S Reference point
T Target point

1. A method for generating a series of n-dimensional magnetic resonance images from an MR bin series obtained by means of an MRI measurement, wherein the MR bin series comprises a plurality of bin frames (f1, f2, f3) with determined MR data, wherein at least one bin frame is undersampled, i.e., has missing MR data in addition to the determined MR data, wherein the bin frames differ by the value of x prespecified parameters (x=1 or greater) under which the MR data were determined, comprising:
a) calculating an n-dimensional preliminary reconstruction kernel from preliminary reference data of a reference frame;
b) determining preliminary reconstruction frames by reconstruction of the MR data missing in the MR bin series by means of the preliminary reconstruction kernel;
c) calculating an n+x-dimensional reconstruction kernel from the MR data of the preliminary reconstruction frames, wherein MR data of different preliminary reconstruction frames are used for the calculation of the n+x-dimensional reconstruction kernels;
d) determining further reconstruction frames by reconstructing the data missing in the bin frames by means of the n+x-dimensional reconstruction kernels;
e) generating n-dimensional magnetic resonance images from the reconstruction frames determined in step (d).

2. The method according to claim 1, characterized in that an echo-planar imaging measurement sequence is used in the MRI measurement.

3. The method according to claim 1, characterized in that the at least one prespecified parameter is the direction and/or the amplitude of the diffusion gradients used in the MRI measurement.

4. The method according to claim 1, characterized in that the at least one prespecified parameter comprises the time coordinate within a cycle.

5. The method according to claim 1, characterized in that the at least one prespecified parameter is the echo time used in the MRI measurement.

6. The method according to claim 1, characterized in that the encoding of the MR data in the MR bin frames is periodic, wherein preferably a GRAPPA or CAIPIRINHA reconstruction method is applied, or in that the encoding of the MR data in the MR bin frames is irregular in at least one dimension, wherein a SPIRIT reconstruction method is preferably applied.

7. The method according to claim 1, characterized in that only bin frames, the values of which for the prespecified parameter lie within a prespecified interval, are used for the reconstruction of the missing MR data.

8. The method according to claim 1, characterized in that the MR bin series has bin frames with different encoding.

9. The method according to claim 8, characterized in that the n-dimensional preliminary reconstruction kernel is a t-GRAPPA kernel.

10. The method according to claim 8, characterized in that the encoding of the MR data of the bin series is periodic, wherein preferably a CAIPIRINHA reconstruction method is applied, or in that the encoding of the MR data of the bin series is irregular in at least one dimension, wherein a SPIRIT reconstruction method is preferably applied.

11. The method according to claim 1, characterized in that steps c) and d) are repeated, wherein the calculation of the n+x-dimensional reconstruction kernel in step c) is carried out from the MR data of the previously determined further reconstruction frames.

12. The method according to claim 1, characterized in that the reconstruction in step (d) takes place in the k-space.
